(19) United States
(12) Patent Application Publication
(10) Pub. No.: US 2015/0234028 A1
(43) Pub. Date: Aug. 20, 2015

(54) State of Charge Gauge Device and State of Charge Gauge Method Thereof

(71) Applicant: Energy Pass Incorporation, Hsinchu City (TW)

(72) Inventor: Ming-Wei Lin, Hsinchu City (TW)

(73) Assignee: Energy Pass Incorporation, Hsinchu City (TW)

(21) Appl. No.: 14/183,525

(22) Filed: Feb. 19, 2014

(51) Int. Cl. G01R 35/00; G01R 31/36

(52) U.S. Cl. CPC G01R 35/005; G01R 31/362

(57) ABSTRACT

A state of charge (SOC) gauge device for a battery includes a voltage variation detection unit, for detecting whether a variation of a battery voltage of the battery reaches a predefined threshold, to generate a detection result; and a coulometer, for calibrating a SOC of the battery according to the detection result.

### BACKGROUND OF THE INVENTION

1. Field of the Invention

The present invention relates to a state of charge (SOC) gauge device and SOC method thereof, and more particularly, to a SOC gauge device and SOC method thereof capable of calibrating a SOC and a current maximum battery capacity of a battery according to a variation of a battery voltage of the battery and an amount of discharge.

2. Description of the Prior Art

Conventionally, a state of charge (SOC), i.e. a battery capacity, of a battery can be gauged by a coulometer or an open circuit voltage (OCV) method. The OCV method relaxes the battery and measures an OCV of the battery to find a corresponding SOC, and the coulometer measures a discharge current or a charge current over a period of time, and then derives the SOC by integration according to a current maximum battery capacity. Therefore, the current maximum battery capacity is required for correctly gauge the SOC, and the current maximum battery capacity is corresponding to a specific charge/discharge cycle the battery has been fully charged and fully discharged, i.e. the more charge/discharge cycles the battery has been fully charged and fully discharged, the lower the current maximum battery capacity is.

However, Lithium iron phosphate (LiMPO4) batteries for electric motors are often fully charged but not fully discharged, i.e. the LiMPO4 batteries for electric cars are often fully charged before driving and not fully discharged after driving, and thus it is inaccurate to determine the current maximum battery capacity by counting charge times.

Besides, the coulometer may have accumulative errors during measurement, i.e. the SOC is overestimated if some instantaneous high currents are not measured due to a low sampling rate, and the OCV method may not correctly measure the SOC due to nonmonotonicity in a flat area of the LiMPO4 battery and requires a long relax time. Thus, there is a need for improvement over the prior art.

### SUMMARY OF THE INVENTION

It is therefore an objective of the present invention to provide a state of charge (SOC) gauge device and SOC method thereof capable of calibrating a SOC and a current maximum battery capacity of a battery according to a variation of a battery voltage of the battery and an amount of discharge.

The present invention discloses a state of charge (SOC) gauge device for a battery. The SOC gauge device includes a voltage variation detection unit, for detecting whether a variation of a battery voltage of the battery reaches a predefined threshold, to generate a detection result; and a coulometer, for calibrating a SOC of the battery according to the detection result.

The present invention further discloses a state of charge (SOC) gauge method for a battery. The SOC gauge method includes detecting whether a variation of a battery voltage of the battery reaches a predefined threshold, to generate a detection result; and calibrating a SOC of the battery according to the detection result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a schematic diagram of a state of charge gauge device according to an embodiment of the present invention.

FIG. 1B is a schematic diagram of a battery voltage of a battery.

FIG. 2 is a schematic diagram of a state of charge gauge process according to an embodiment of the present invention.

### DETAILED DESCRIPTION

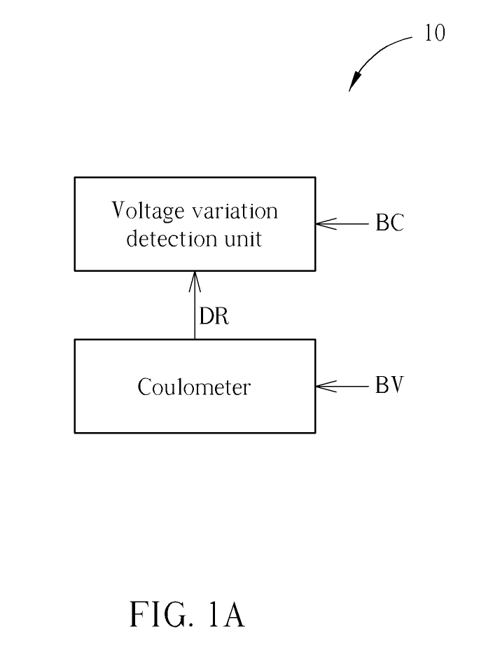

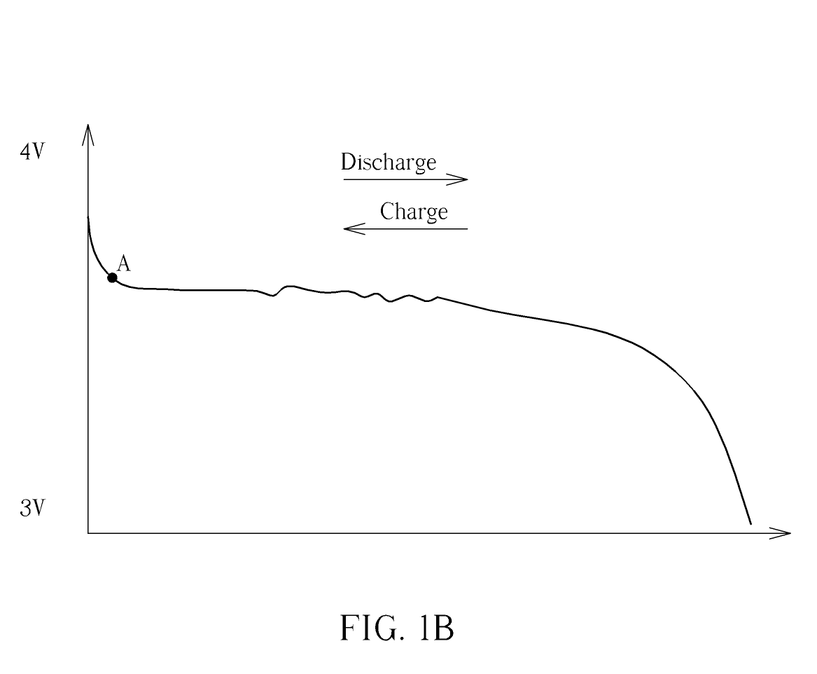

Please refer to FIG. 1A, which is a schematic diagram of a state of charge (SOC) gauge device 10 according to an embodiment of the present invention. As shown in FIG. 1A, the SOC gauge device 10 measures a SOC of a battery, which is preferably a Lithium iron phosphate (LiMPO4) battery for an electric motor, and includes a voltage variation detection unit 100 and a coulometer 102. In short, the voltage variation detection unit 100 detects whether a variation of a battery voltage BV of the battery is greater than a predefined threshold, to generate a detection result DR, and then the coulometer 102 calibrates the SOC of the battery according to the detection result DR. Under such a situation, since the SOC of the battery reaches a specific SOC value when the variation of the battery voltage BV of the battery reaches the predefined threshold, the coulometer 102 can calibrate the measured SOC of the battery according to the specific SOC value. As a result, the coulometer 102 can eliminate accumulative errors resulting from some unmeasured instantaneous currents due to a low sampling rate, to derive the accurate SOC of the battery.

Specifically, please refer to FIG. 1B, which is a schematic diagram of the battery voltage BV of the battery, wherein a discharge direction is from left to right and a charge direction is from right to left. As shown in FIG. 1B, a point A is where the variation of the battery voltage of the battery reaches the predefined threshold and the SOC of the battery reaches a specific SOC value which approximates 100%, e.g. 97%. Under such a situation, the coulometer 102 can calibrate an amount of discharge during a discharge period according to a charge current and the detection result DR.

For example, if the battery is actually discharged to a SOC of 60% and the coulometer 102 overestimates the SOC as 65% due to accumulative errors resulting from some unmeasured instantaneous currents, when the detection result DR indicates the variation of the battery voltage reaches the predefined threshold and thus the SOC is 97%, the coulometer 102 can first calibrate the SOC of the battery as 97% and then calibrate the amount of discharge by utilizing 97% minus the charge current times a charge time to derive the amount of discharge as 40% (100%-60%) since the charge current is smaller than the discharge current and can be measured accurately by the coulometer 102. As a result, the coulometer 102 can correctly derive the SOC and the amount of discharge of the battery by eliminating accumulative errors resulting from some unmeasured instantaneous currents due to the low sampling rate.

On the other hand, the coulometer 102 also calibrates a specific charge/discharge cycle which the battery has been charged and discharged according to the amount of discharge during the discharge period. Specifically, in one charge/discharge cycle, the battery is discharged and charged at least one time and a total amount of discharge is a current maximum battery capacity, i.e. 100%. For example, if the battery is first discharged to 50% and then fully charged to 100%, the battery has to be discharged to 50% and then fully charged to 100% again for the coulometer 102 to consider the battery experiences one charge/discharge cycle.

Under such a situation, since a current maximum battery capacity is required for the coulometer 102 to correctly measure the SOC, and current maximum battery capacity is corresponding to the specific charge/discharge cycle which the battery has been fully charged and fully discharged, the coulometer 102 can also calibrate the current maximum battery capacity according to the specific charge/discharge cycle derived by the above manner. As a result, the coulometer 102 can correctly determine the specific charge/discharge cycle and the corresponding current maximum battery capacity of the battery.

Noticeably, the above embodiment is to calibrate the SOC according to the variation of the battery voltage of the battery and calibrate the current maximum battery capacity of the battery according to the amount of discharge and the defined charge/discharge cycle, so as to correctly determine the SOC of the battery. Those skilled in the art should make modifications or alterations accordingly. For example, rather than utilizing the point A shown in FIG. 1B with the specific SOC value of 97% in the upper end to determine whether the variation of the battery voltage BV is greater than a predefined threshold for calibration, the voltage variation detection unit 100 can also utilize another point with a specific SOC value which approximates 0%, e.g. 3%, in the lower end to determine whether the variation of the battery voltage BV is greater than another predefined threshold for calibration. Besides, in the above embodiment, methods of calibrating the SOC according to the variation of the battery voltage of the battery and calibrating the current maximum battery capacity of the battery according to the amount of discharge and the redefined charge/discharge cycle are applied together, i.e. calibrating the amount of discharge according to the variation of the battery voltage and then calibrating the current maximum battery capacity accordingly, but can be applied separately in other embodiments while retaining respective merits.

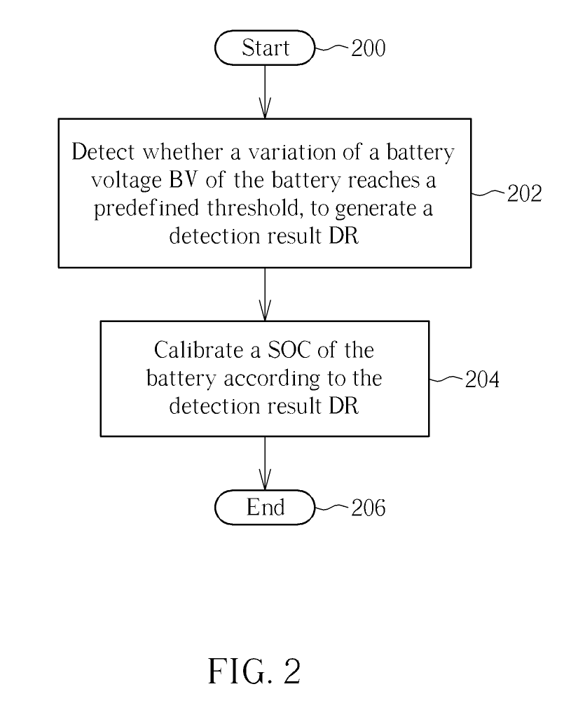

Operations of the SOC gauge device 10 can be summarized into a SOC gauge process 20 shown in FIG. 2. The SOC gauge process 20 includes following steps:

Step 200: Start.

Step 202: Detect whether a variation of a battery voltage BV of the battery reaches a predefined threshold, to generate a detection result DR.

Step 204: Calibrate a SOC of the battery according to the detection result DR.

Step 206: End.

Details of the SOC gauge process 20 can be derived by referring to the above descriptions, and are not narrated hereinafter.

In the prior art, LiMPO4 batteries for electric motors are often fully charged but not fully discharged, and thus it is inaccurate to determine the current maximum battery capacity by counting charge times. Besides, the conventional coulometer may have accumulative errors during measurement resulting from some unmeasured instantaneous high currents due to a low sampling rate, and the OCV method may not correctly measure the SOC due to nonmonotonicity in a flat area of the LiMPO4 battery and requires a long relax time. In comparison, the present invention calibrates the SOC and the amount of discharge according to the variation of the battery voltage of the battery, and then calibrates the current maximum battery capacity of the battery according to the amount of discharge and the defined charge/discharge cycle, so as to correctly determine the SOC of the battery.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A state of charge (SOC) gauge device for a battery, comprising:
a voltage variation detection unit, for detecting whether a variation of a battery voltage of the battery reaches a predefined threshold, to generate a detection result; and
a coulometer, for calibrating a SOC of the battery according to the detection result.

2. The SOC gauge device of claim 1, wherein the SOC of the battery reaches a specific SOC value when the variation of the battery voltage of the battery reaches the predefined threshold.

3. The SOC gauge device of claim 2, wherein the specific SOC value approximates 100%.

4. The SOC gauge device of claim 1, wherein the coulometer calibrates an amount of discharge during a discharge period according to a charge current and the detection result.

5. The SOC gauge device of claim 1, wherein the coulometer calibrates a specific charge/discharge cycle which the battery has been charged and discharged according to an amount of discharge during the discharge period.

6. The SOC gauge device of claim 5, wherein the battery is discharged and charged at least one time and a total amount of discharge is a current maximum battery capacity in one charge/discharge cycle.

7. The SOC gauge device of claim 5, wherein the coulometer calibrates a current maximum battery capacity according to the specific charge/discharge cycle.

8. A state of charge (SOC) gauge method for a battery, comprising:
detecting whether a variation of a battery voltage of the battery reaches a predefined threshold, to generate a detection result; and
calibrating a SOC of the battery according to the detection result.

9. The SOC gauge method of claim 8, wherein the SOC of the battery reaches a specific SOC value when the variation of the battery voltage of the battery reaches the predefined threshold.

10. The SOC gauge method of claim 9, wherein the specific SOC value approximates 100%.

11. The SOC gauge method of claim 8 further comprising:
calibrating an amount of discharge during a discharge period according to a charge current and the detection result.

12. The SOC gauge method of claim 8 further comprising:
calibrating a specific charge/discharge cycle which the battery has been charged and discharged according to an amount of discharge during the discharge period.

13. The SOC gauge device of claim 12, wherein the battery is discharged and charged at least one time and a total amount of discharge is a current maximum battery capacity in one charge/discharge cycle.

14. The SOC gauge method of claim 12 further comprising:
calibrating a current maximum battery capacity according to the specific charge/discharge cycle.
